(19) United States
(12) Patent Application Publication
(10) Pub. No.: US 2017/0365641 A1
(43) Pub. Date: Dec. 21, 2017

(54) NON-VOLATILE DOUBLE SCHOTTKY BARRIER MEMORY CELL

(71) Applicant: Western Digital Technologies, Inc., Irvine, CA (US)

(72) Inventor: Daniel BEDAU, San Jose, CA (US)

(73) Assignee: HGST Netherlands B.V.

(21) Appl. No.: 15/184,838

(22) Filed: Jun. 16, 2016

(51) Int. Cl. H01L 27/24; H01L 45/00

(52) U.S. Cl. CPC H01L 27/2436; H01L 45/146; H01L 45/1226; H01L 45/1253

(57) ABSTRACT

A three terminal ReRAM device, which combines a Schottky barrier transistor and a Schottky barrier ReRAM into a single device is provided. The Schottky transistor memory device includes a source region, a drain region, and a gate electrode. Between the source and drain regions, the ReRAM material is present. The ReRAM material can include a metal oxide, such as zinc or hafnium oxide. A Schottky barrier forms naturally between the drain region and the ReRAM material. As voltage is applied to the gate electrode and the source region, the Schottky barrier breaks down, leading to the formation of a filament across the drain region and the ReRAM material. The filament is non-volatile and short-circuits the reverse-biased barrier, keeping the device in a low resistance state. The filament can be removed by reversing the polarity of the voltage such that the device switches back to a high resistance state.

### BACKGROUND OF THE DISCLOSURE

### Field of the Disclosure

Embodiments of the present disclosure generally relate to a non-volatile memory device, specifically a resistive random-access memory (ReRAM) device.

### Description of the Related Art

Non-volatile memory is computer memory capable of retaining stored information even after having been power cycled. Non-volatile memory is becoming more popular because of its small size/high density, low power consumption, fast read and write rates, and retention. Flash memory is a common type of non-volatile memory because of its high density and low fabrication costs. Flash memory is a transistor-based memory device that uses multiple gates per transistor and quantum tunneling for storing information on its memory device. However, flash memory uses a block-access architecture that can result in long access, erase, and write times. Flash memory also suffers from low endurance, high power consumption, and scaling limitations.

Storage demand and the constantly increasing speed of electronic devices require new improvements for non-volatile memory. New types of memory, such as resistive random access memory (ReRAM), are being developed as flash memory replacements to meet these demands. Resistive memories refer to technology that uses varying cell resistance to store information. ReRAM refers to the subset that uses metal oxides as the storage medium. In order to switch a ReRAM cell, an external voltage with specific polarity, magnitude, and duration is applied. However, ReRAM typically operates at a significantly high current. As such, ReRAM necessitates a large sized access transistor for each cell which ultimately increases the area and cost.

Thus, there is a need in the art for an improved ReRAM memory device.

### SUMMARY OF THE DISCLOSURE

A three terminal ReRAM device, which combines a Schottky barrier transistor and a Schottky barrier ReRAM into a single device is provided. The Schottky transistor memory device includes a source region, a drain region, and a gate electrode. Between the source and drain regions, the ReRAM material is present. The ReRAM material can include a metal oxide, such as zinc or hafnium oxide. A Schottky barrier forms naturally between the drain region and the ReRAM material. As voltage is applied to the gate electrode and the source region, the Schottky barrier breaks down, leading to the formation of a filament across the drain region and the ReRAM material. The filament is non-volatile and short-circuits the reverse-biased barrier, keeping the device in a low resistance state. The filament can be removed by reversing the polarity of the voltage such that the device switches back to a high resistance state.

In one embodiment, a memory device comprises an insulating layer; a source region disposed on the insulating layer; a drain region disposed on the insulating layer; a ReRAM material layer disposed on the insulating layer in between the source region and the drain region; and a gate electrode disposed over the ReRAM material layer.

In another embodiment, a memory device comprises an insulating layer; a source region disposed on the insulating layer; a drain region disposed on the insulating layer; a ReRAM material layer disposed on the insulating layer between the source region and the drain region; a gate electrode disposed over the ReRAM material layer; and a conductive anodic filament extending from the drain region to the ReRAM material layer.

In another embodiment, a memory array comprising one or more memory devices is discloses where at least one of the devices comprises an insulating layer; a source region disposed on the insulating layer; a drain region disposed on the insulating layer; a ReRAM material layer disposed on the insulating layer in between the source region and the drain region; a gate electrode disposed over the ReRAM material layer; and a conductive anodic filament extending from the drain region to the ReRAM material layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A shows a schematic illustration of a memory device according to one embodiment.

FIG. 1B shows a schematic illustration of the memory device of FIG. 1A after applying voltage.

FIG. 1C shows a schematic illustration of the memory device of FIG. 1B after a reverse voltage is applied.

FIG. 2 shows a schematic illustration of a memory array including one or more Schottky transistor memory devices.

FIG. 3 is a schematic illustration of a unipolar memory device.

FIG. 4 is a schematic illustration of a memory device according to one embodiment.

FIG. 5 is a schematic illustration of a memory device according to another embodiment.

FIG. 6 is a schematic illustration of a memory device according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

A three terminal ReRAM device, which combines a Schottky barrier transistor and a Schottky barrier ReRAM into a single device is provided. The Schottky transistor memory device includes a source region, a drain region, and a gate electrode. Between the source and drain regions, the ReRAM material is present. The ReRAM material can include a metal oxide, such as zinc or hafnium oxide. A Schottky barrier forms naturally between the drain region and the ReRAM material. As voltage is applied to the gate electrode and the source region, the Schottky barrier breaks down, leading to the formation of a filament across the drain region and the ReRAM material. The filament is non-volatile and short-circuits the reverse-biased barrier, keeping the device in a low resistance state. The filament can be removed by reversing the polarity of the voltage such that the device switches back to a high resistance state.

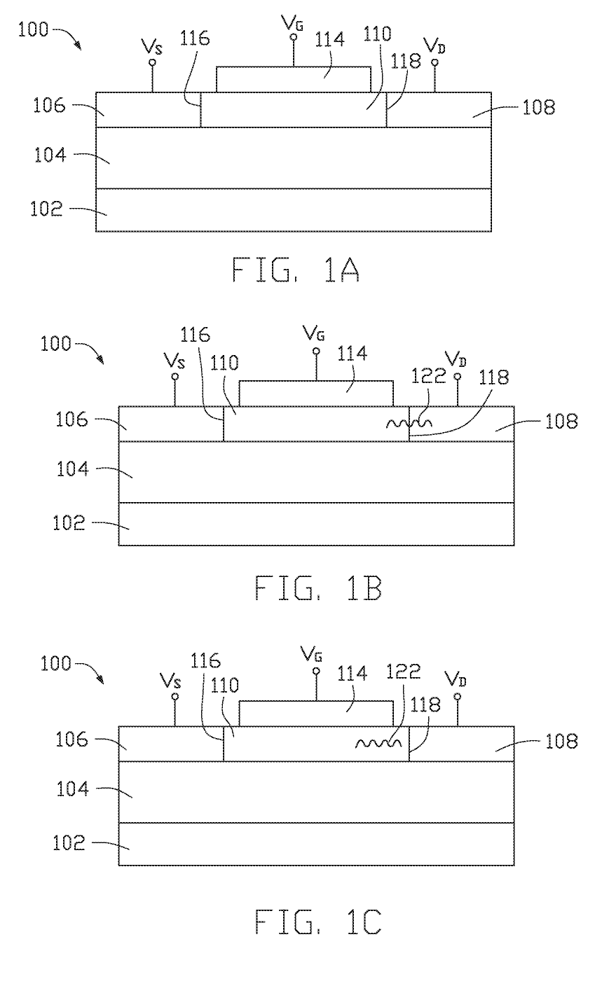

FIG. 1A shows a schematic illustration of a memory device 100 according to one embodiment. The memory device 100 may be a three terminal ReRAM device and/or a field effect transistor. The memory device 100 may include a substrate 102, and an insulating layer 104 disposed on the substrate 102. A source region 106 and a drain region 108 may be disposed on the insulating layer 104. The source region 106 is not in contact with the drain region 108. A ReRAM material layer 110 may be disposed between the source region 106 and the drain region 108. The ReRAM material layer 110 may be in contact with both the source region 106 and the drain region 108. A gate electrode 114 may be disposed over the ReRAM material layer 110. In one embodiment, the gate electrode 114 extends laterally substantially the same distance as the ReRAM material layer 110.

In one embodiment, the insulating layer 104 comprises silicon dioxide (SiO₂). It is to be understood that other materials are contemplated as well, such as silicon nitride and silicon oxynitride. The gate electrode 114 may comprises polycrystalline silicon. The source region 106 and the drain region 108 may comprise a metal, such as platinum, ruthenium, or nickel. Additionally, the source region 106 and the drain region 108 may be a silicide selected from the group including but not limited to the following: platinum silicide (PtSi), nickel silicide (NiSi), sodium silicide (Na₂Si), magnesium silicide (Mg₂Si), titanium silicide (TiSi₂) or tungsten silicide (WSi₂). The source region 106 may be comprised of different materials than the drain region 108. In one embodiment, the gate electrode 114 may comprise p-type or n-type doped metal oxide while the ReRAM material layer 110 may comprise the same metal oxide material, but of the opposite doping.

The ReRAM material layer 110 may comprise a metal oxide such as an oxide selected from the group including, but not limited to, the following: hafnium oxide (HfO₂), titanium oxide (TiO₂), tantalum oxide (TaO₂), indium-tin-oxide (ITO), zinc oxide (ZnO), vanadium oxide (VO₂), tungsten oxide (WO₂), zirconium oxide (ZrO₂), copper oxide, or nickel oxide and combinations thereof.

One or more Schottky barriers are formed in the Schottky transistor memory device 100 by the combination of materials used in the source region 106, ReRAM material layer 110, and drain region 108. A Schottky barrier creates a potential energy barrier for electrons formed at a conductive layer, a metal-semiconductor junction, or between two oxide layers.

The source region 106 and the drain region 108 may comprise a metal, a metal oxide, or a doped metal oxide. If the source region 106 and/or drain region 108 is doped, the doping may occur through ion implantation. If the source region 106 and/or drain region 108 comprises a metal oxide, the metal oxide may comprise the same metal oxide as the ReRAM material layer 110, but have a different oxidation state. Alternatively, the metal oxide of the source region 106 and/or drain region 108 may comprise a different composition than the metal oxide of the ReRAM material layer 110. In one embodiment, the source region 106 comprises a different material than the drain region 108. In one embodiment, the ReRAM material layer 110 comprises TaOₓ where x=1.3, and the drain region 108 comprises TaO_{y} where 2.5>y>1.5.

In one embodiment, a first Schottky barrier 116 may be formed at the interface between the source region 106 and the ReRAM material layer 110, and a second Schottky barrier 118 may be formed at the interface between the drain region 108 and the ReRAM material layer 110. One Schottky barrier limits an electrical current in one direction while the other Schottky barrier limits a current in the opposite direction. The first Schottky barrier 116 may limit an electrical current in a forward direction and is conducting from the source region 106 to the drain region 108. The first Schottky barrier 116 is optional, and may not be present in the device 100. In one embodiment, the first Schottky barrier 116 is eliminated, such as by annealing. The second Schottky barrier 118 limits an electrical current in the opposite or reverse direction, isolating from the drain region 108 to the source region 106.

When two different resistive states are identified for a memory device (i.e., a high resistive state and a low resistive state), one state may be associated with a logic “zero,” while the other state may be associated with a logic “one” value. The combination of the Schottky barrier 118 provides a high resistive state, or a non-conducting state, where current cannot flow. At zero voltage, the Schottky barrier 118 prevents current from flowing from the source region 106 to the drain region 108. As an electrical field or voltage is applied through the gate electrode 114, the second Schottky barrier 118 may be switched off and current may flow between the source region 106 and the drain region 108 due to formation of a conductive anodic filament.

FIG. 1B shows a schematic illustration of the Schottky transistor memory device 100 of FIG. 1A after applying voltage to both the source region 106 and the gate electrode 114. The Schottky transistor memory device 100 may include the substrate 102, the insulating layer 104, the source region 106, the drain region 108, the ReRAM material layer 110, the gate electrode 114, the first Schottky barrier 116, the second Schottky barrier 118, and a conductive anodic filament (CAF) 122. A voltage may be applied to the source region 106. By applying a gate voltage V_{G}, the breakdown voltage of the second Schottky barrier 118 is reduced, and simultaneously, the CAF 122 forms across the second Schottky barrier 118 from the ReRAM material layer 110 to the drain region 108. The formation of the CAF 122 shorts the second Schottky barrier 118, bringing the device 100 to the low resistance state. The device 100 is non-volatile when in the low resistance state, and no voltage is required to maintain the low resistance state. Additionally, the CAF 122 remains even when the voltage is no longer applied. As long as the CAF 122 is in place, the device 100 operates in the low resistance state, regardless of the gate voltage. When two different resistive states are identified for a ReRAM device (i.e., a high resistive state and a low resistive state), one state may be associated with a logic “zero,” while the other state may be associated with a logic “one” value. As such, the formation of the CAF 122 across the second Schottky barrier 118 provides for a low resistive state, or a state associated with either 0 or 1.

FIG. 1C shows a schematic illustration of the Schottky transistor memory device 100 of FIG. 1B after a reverse voltage is applied. The Schottky transistor memory device 100 may include the substrate 102, the insulating layer 104, the source region 106, the drain region 108, the ReRAM material layer 110, the gate electrode 114, the first Schottky barrier 116, the second Schottky barrier 118, and the CAF 122. To return the Schottky transistor memory device 100 to a high resistive state, a reverse voltage is applied to the drain region 108, and the second Schottky barrier 118 is restored. The reverse voltage breaks the CAF 122, and the second Schottky barrier 118 isolates the drain region 108 from the source region 106. The second Schottky barrier 118 provides a high resistive state where current cannot flow, thus representing a state associated with either 0 or 1. A portion of the CAF 122 may still be present in the ReRAM material layer 110. Reversing the polarity of the voltage makes the gate electrode 114 conductive, which may be utilized in readout circuitry to measure the state of the device 100.

A new filament may then be formed by applying voltage to the source region 106 and the gate electrode 114, like shown in FIG. 1B. Thus, CAF 122 formation can be controlled by the polarity of the voltage of the gate and the drain. The CAF 122 formation across the second Schottky barrier 118 advantageously provides for a low resistive state, whereas the CAF 122 breakage and the second Schottky barrier 118 restoration provide for a high resistive state. The two resistive states thus allow for a non-volatile memory device in a Schottky barrier field effect transistor. A separate transistor is not required for such a ReRAM device, advantageously resulting in a more cost-effective and compactly designed ReRAM device. Additionally, the non-volatile Schottky barrier field effect transistor is a very fast element with very low energy consumption. As such, the present disclosure may be used for ultra-low power non-volatile logic in IoT application, in-memory computation by combining logic and memory, and as a building block for non-volatile memory devices in two dimensions (2D) and three dimensions (3D).

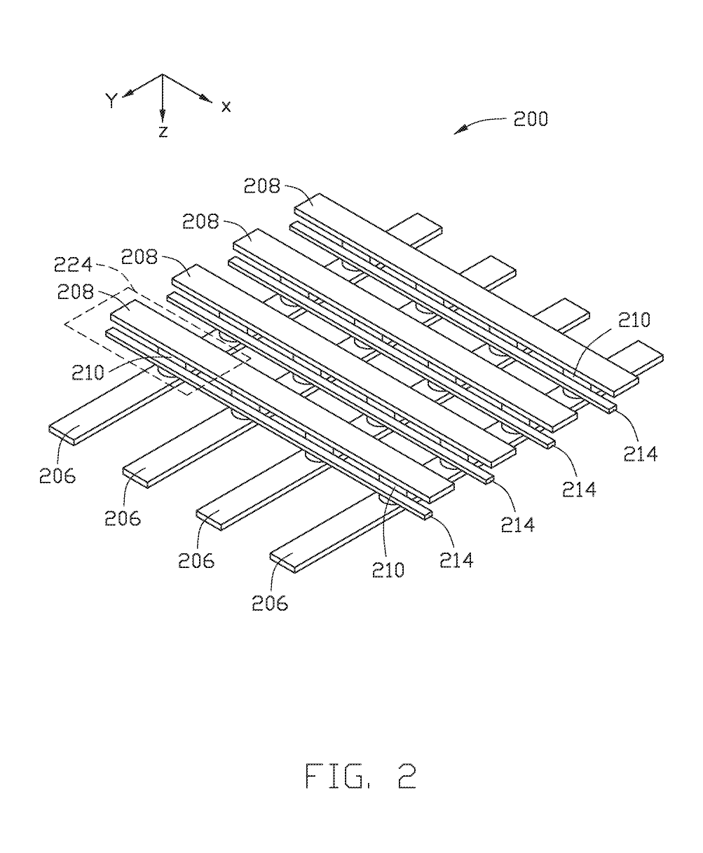

FIG. 2 shows a schematic illustration of a memory device array 200 including one or more Schottky transistor memory devices. The memory device array 200 may include one or more Schottky transistor devices similar to the Schottky transistor device 100 shown in FIGS. 1A-1C. In one embodiment, each device in the array 200 is a Schottky transistor memory device 100. The box labelled 224 represents one Schottky transistor memory device, such as the Schottky transistor memory device 100 shown in FIGS. 1A-1C. The memory device array 200 of FIG. 2 shows sixteen memory devices comprising the array, however, the memory device array 200 may be comprised of any number of memory devices. The memory device array 200 may include one or more source regions 206, one or more drain regions 208, one or more ReRAM material layers 210, and one or more gate regions 214. The memory device array 200 may further include an insulating layer, and a substrate, none of which are shown. In the array 200, no two ReRAM material layers 210 share both a common source region 206 and a common drain region 208.

In the memory device array 200, the source regions 206 are longitudinally disposed in the x-direction. The drain regions 208 and the gate electrodes 214 are longitudinally disposed in the z-axis. The ReRAM material layers 210 are longitudinally disposed in the y-axis. The source regions 206 are displaced from both the drain regions 208 and the gate electrodes 214 in the y-direction. While the gate electrodes 214 are in contact with the ReRAM material layers 210, the gate electrodes 214 are not in contact with the source regions 206 or the drain regions 208. The ReRAM material layers 210 are in contact with the source regions 206, the drain regions 208, and the gate electrodes 214. The source regions 206 are perpendicular to both the drain regions 208 and the gate electrodes 214. The drain regions 208 are parallel to the gate electrodes 214; however, the drain regions 208 are displaced from the gate electrodes 214 in the x-axis and the y-axis. A xyz-axis is included in FIG. 1A for clarity.

To select a single Schottky transistor memory device, such as the device in box 224, a voltage may be applied to the source region 206 and gate electrode 214 in contact with the desired ReRAM material layer 210. By applying a voltage to both the gate electrode 214 and the source region 206, a CAF (not shown) forms across the ReRAM material layer 210 to the drain region 208. The large voltage leads to the breakdown of the second Schottky barrier (not shown) and the formation of the CAF across the second Schottky barrier. After the formation of the CAF, the Schottky transistor memory device switches to a low resistance state representing a state associated with either 0 or 1. Reversing the polarity of the voltage breaks the CAF and restores the second Schottky barrier. Thus, the second Schottky barrier once again isolates the drain region 208 from the gate electrode 214 and the source region 206. The Schottky barrier provides a high resistive state where current cannot flow, thus representing a state associated with either 0 or 1. Reversing the polarity of the voltage makes the gate electrode 214 conductive, which allows the array 200 to be utilized in readout circuitry in order to measure the state of each device in the array 200.

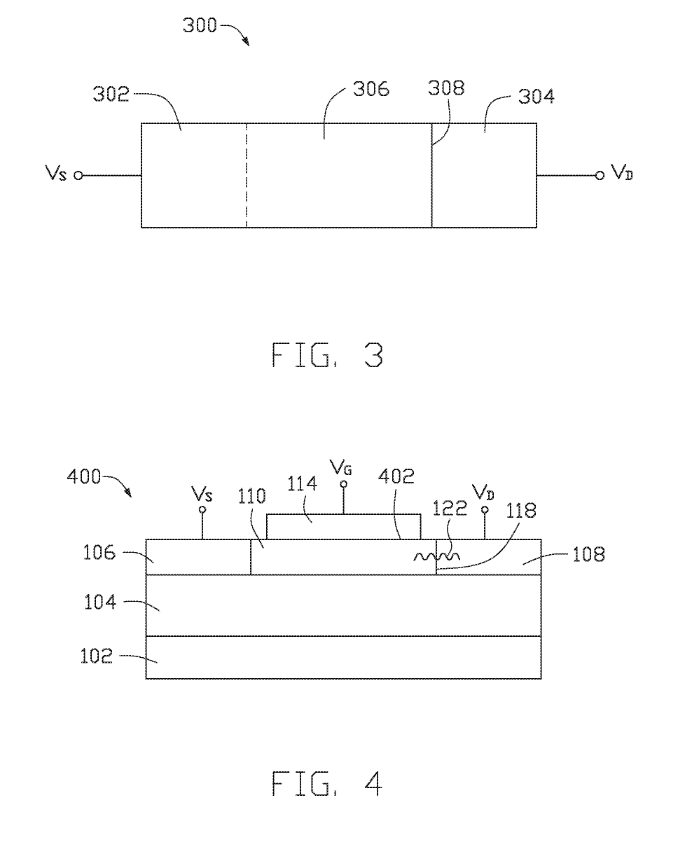

FIG. 3 is a schematic illustration of a unipolar memory device 300. The device 300 includes a source region 302, drain region 304 and a ReRAM material region 306. The materials for the source region 302, drain region 304 and ReRAM material region 306 may be the same as described above with regards to FIGS. 1A-1C. A Schottky barrier 308 is present between the drain region 304 and the ReRAM material region 306 until a conductive anodic filament is formed. No Schottky barrier is present between the source region 302 and the ReRAM material region 306. The dashed line is merely to show a boundary of the regions without intention of a Schottky barrier being present or illustrated.

FIG. 4 is a schematic illustration of a memory device 400 according to one embodiment. Once the conductive anodic filament 122 is formed, the gate electrode 114 needs to be isolated so that no current flows to the gate electrode 114. In the embodiment shown in FIG. 4, a Schottky barrier 402 is present. Thus, prior to formation of the CAF 122, there is a Schottky barrier 402 present between the gate electrode 114 and the ReRAM material layer 110 and also a Schottky barrier 118 between the ReRAM material layer 110 and the drain region 108.

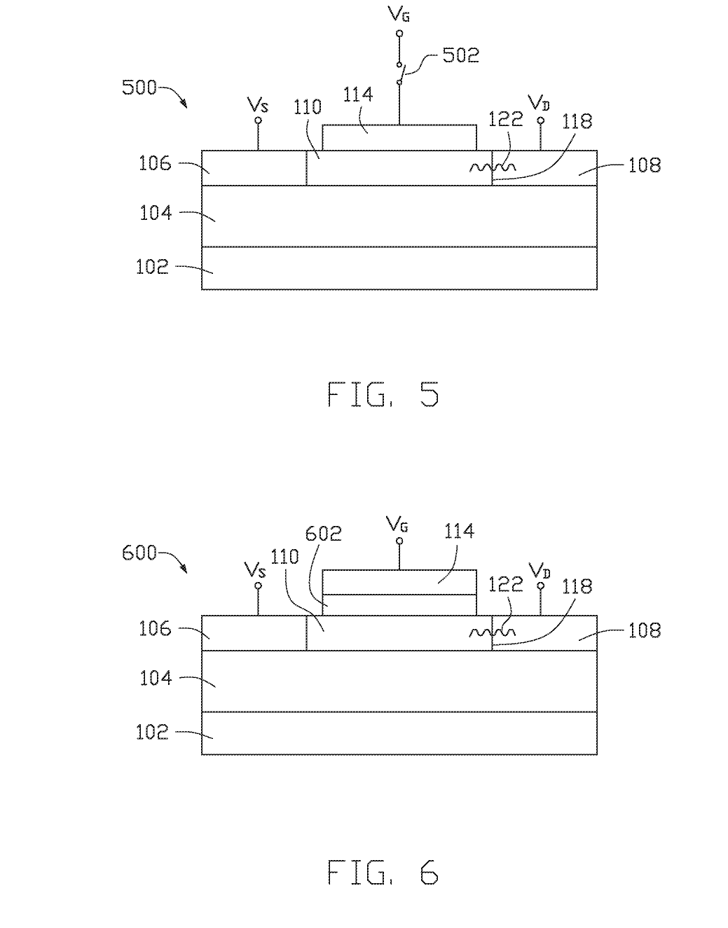

FIG. 5 is a schematic illustration of a memory device 500 according to another embodiment. In FIG. 5, a switch 502 is present to switch the gate electrode 114 from being floating to being biased. FIG. 6 is a schematic illustrating of a memory device of claim 600 according to another embodiment. In FIG. 6, a highly resistive layer 602 is present between the ReRAM material layer 110 and the gate electrode 114. The highly resistive layer 602 may comprise a material selected from the group consisting of TaN, RuO₂, PbO, Bi₂Ru₂O₇, NiCr, and combinations thereof.

The three terminal ReRAM device having a Schottky barrier and a ReRAM material layer switches from a low resistive state to a high resistive state using the conductive anodic filament, resulting in a non-volatile field effect transistor. The CAF short-circuits the reverse-biased barrier, maintaining the device in a low resistance state. Removing the CAF by reversing the polarity of the voltage switches the device back to a high resistance state. Reversing the polarity of the voltage makes the gate conductive, allowing for the memory state of the device to be read through the gate. Thus, the Schottky transistor memory device advantageously combines computation and memory by having a three terminal structure that is able to switch electronic signals, retain information when the power is turned off, and have the state of the device readout through the gate.

While the foregoing is directed to embodiments of the present disclosure, other and further embodiments of the disclosure may be devised without departing from the basic scope thereof, and the scope thereof is determined by the claims that follow.

What is claimed is:

1. A memory device, comprising:
an insulating layer;
a source region disposed on the insulating layer;
a drain region disposed on the insulating layer;
a ReRAM material layer disposed on the insulating layer in between the source region and the drain region; and
a gate electrode disposed over the ReRAM material layer.

2. The device of claim 1, wherein the ReRAM material layer comprises a metal oxide material.

3. The device of claim 2, wherein the metal oxide material comprises a material selected from the group consisting of zinc oxide, hafnium oxide, tantalum oxide, titanium oxide, vanadium oxide, tungsten oxide, zirconium oxide, nickel oxide, copper oxide and combinations thereof.

4. The device of claim 1, wherein the ReRAM material layer comprises a metal oxide having a first oxidation state, the drain region comprises the same metal oxide having a second oxidation state different that the first oxidation state.

5. The device of claim 1, wherein ReRAM material layer comprises doped metal oxide.

6. The device of claim 1, wherein ReRAM material layer comprises a metal oxide having a first composition and the drain region comprises a metal oxide having a second composition different than the first composition.

7. The device of claim 1, wherein the ReRAM material layer comprises a metal oxide and the drain region comprises a metal.

8. The device of claim 1, wherein the gate electrode is disposed on the ReRAM material layer and a Schottky barrier is present between the gate electrode and the ReRAM material layer.

9. The device of claim 1, wherein a resistive or dielectric layer having a resistance greater than a resistance of the gate electrode is disposed between the gate electrode and the ReRAM material layer.

10. The device of claim 9, wherein the resistive layer comprises a material selected from the group consisting of TaN, RuO₂, PbO, Bi₂Ru₂O₇, NiCr, and combinations thereof.

11. A memory device, comprising:
an insulating layer;
a source region disposed on the insulating layer;
a drain region disposed on the insulating layer;
a ReRAM material layer disposed on the insulating layer between the source region and the drain region;
a gate electrode disposed over the ReRAM material layer; and
a conductive anodic filament extending from the drain region to the ReRAM material layer.

12. The device of claim 11, wherein the ReRAM material layer comprises a metal oxide material.

13. The device of claim 12, wherein the metal oxide material comprises a material selected from the group consisting of zinc oxide, hafnium oxide, tantalum oxide, titanium oxide, vanadium oxide, tungsten oxide, zirconium oxide, nickel oxide, copper oxide, PCMO and combinations thereof.

14. The device of claim 11, wherein the ReRAM material layer comprises a metal oxide having a first oxidation state, the drain region comprises the same metal oxide having a second oxidation state different that the first oxidation state.

15. The device of claim 11, wherein ReRAM material layer comprises doped metal oxide.

16. The device of claim 11, wherein ReRAM material layer comprises a metal oxide having a first composition and the drain region comprises a metal oxide having a second composition different than the first composition.

17. The device of claim 11, wherein the ReRAM material layer comprises a metal oxide and the drain region comprises a metal.

18. The device of claim 11, wherein the gate electrode is disposed on the ReRAM material layer and a Schottky barrier is present between the gate electrode and the ReRAM material layer.

19. The device of claim 11, wherein a resistive layer having a resistance greater than a resistance of the gate electrode is disposed between the gate electrode and the ReRAM material layer.

20. The device of claim 19, wherein the resistive layer comprises a material selected from the group consisting of TaN, RuO₂, PbO, Bi₂Ru₂O₇, NiCr, and combinations thereof.

21. A memory array comprising one or more memory devices, at least one of the devices comprising:
an insulating layer;
a source region disposed on the insulating layer;
a drain region disposed on the insulating layer;
a ReRAM material layer disposed on the insulating layer in between the source region and the drain region;
a gate electrode disposed over the ReRAM material layer; and
a conductive anodic filament extending from the drain region to the ReRAM material layer.

22. The memory array of claim 21, wherein the ReRAM material layer comprises a metal oxide material.

23. The memory array of claim 22, wherein the metal oxide material comprises a material selected from the group consisting of zinc oxide, hafnium oxide, tantalum oxide, titanium oxide, vanadium oxide, tungsten oxide, zirconium oxide, nickel oxide, copper oxide and combinations thereof.

24. The memory array of claim 21, wherein the ReRAM material layer comprises a metal oxide having a first oxidation state, the drain region comprises the same metal oxide having a second oxidation state different that the first oxidation state.

25. The memory array of claim 21, wherein ReRAM material layer comprises doped metal oxide.

26. The memory array of claim 21, wherein ReRAM material layer comprises a metal oxide having a first composition and the drain region comprises a metal oxide having a second composition different than the first composition.

27. The memory array of claim 21, wherein the ReRAM material layer comprises a metal oxide and the drain region comprises a metal.

28. The memory array of claim 21, wherein the gate electrode is disposed on the ReRAM material layer and a Schottky barrier is present between the gate electrode and the ReRAM material layer.

29. The memory array of claim 21, wherein a resistive layer having a resistance greater than a resistance of the gate electrode is disposed between the gate electrode and the ReRAM material layer.

30. The memory array of claim 29, wherein the resistive layer comprises a material selected from the group consisting of TaN, RuO₂, PbO, Bi₂Ru₂O₇, NiCr, and combinations thereof.
